(19) United States
(12) Patent Application Publication
(10) Pub. No.: US 2020/0235658 A1
(43) Pub. Date: Jul. 23, 2020

(54) DC/DC CONVERTER AND OPERATION METHOD THEREOF

(71) Applicant: BravoTek Electronics Co., Ltd., Zhubei City (TW)

(72) Inventors: Yi-Sheng CHEN, Zhubei City (TW); Yu-Shen LIN, Zhubei City (TW); Wei-Hsin WEI, Zhubei City (TW)

(21) Appl. No.: 16/396,110

(22) Filed: Apr. 26, 2019

Related U.S. Application Data
(60) Provisional application No. 62/795,055, filed on Jan. 22, 2019.

(51) Int. Cl. H02M 3/04; H03K 5/24; H02M 1/32

(52) U.S. Cl. CPC H02M 3/04; H02M 2001/0009; H02M 1/32; H03K 5/24

(57) ABSTRACT

An operation method for a DC/DC converter includes: using a power stage for converting a DC input voltage into a DC output voltage, the power stage including an inductor; detecting whether the DC output voltage has an overshoot when the DC/DC converter is switched from a heavy loading into a light loading; when it is determined that the DC output voltage has the overshoot, forcing the DC/DC converter for additionally maintaining at a force continuous conduction mode (CCM) and thus discharging the DC output voltage by the inductor, and controlling the DC/DC converter switching from the force CCM into a discontinuous conductor mode (DCM).

This application claims the benefit of U.S. provisional application Ser. No. 62/795,055, filed Jan. 22, 2019, the subject matter of which is incorporated herein by reference.

### TECHNICAL FIELD

The disclosure relates in general to a DC/DC converter and an operation method thereof.

### BACKGROUND

In tradition, a DC (direct current)/DC converter is operated in a continuous conduction mode (CCM) or a discontinuous conduction mode (DCM) depending on the load condition. In CCM, the DC/DC converter is at heavy loading, the flowing-in current and the flowing-out current of the inductor are continuous and energy will be left some after energy release. On the contrary, in DCM, the DC/DC converter is at light loading, the flowing-in current and the flowing-out current of the inductor are discontinuous and energy stored in the inductor will be totally released.

FIG. 1 shows an output voltage waveform and an inductor current waveform of the prior DC/DC converter. While the loading is switched from the heavy loading to the light loading in short time, the inductor current will be suddenly reduced (from high inductor current to 0) and the output voltage of the DC/DC converter has overshoot. Also, the power switches of the power stage of the DC/DC converter are all turned off. Thus, the overshoot of the output voltage of the DC/DC converter will be only discharged by the loading and thus the discharge speed is very slow.

### SUMMARY

According to one embodiment, provided is a DC/DC converter including: a power stage for converting a DC input voltage into a DC output voltage, the power stage including an inductor; an overshoot detector for detecting whether the DC output voltage has an overshoot when the DC/DC converter is switched from a heavy loading into a light loading; and a main control loop coupled to the power stage and the overshoot detector, when the overshoot detector determines that the DC output voltage has the overshoot, the main control loop forcing the DC/DC converter for additionally maintaining at a force continuous conduction mode (CCM) and thus the inductor discharging the DC output voltage, and then the main control loop controlling the DC/DC converter switching from the force CCM into a discontinuous conductor mode (DCM).

According to another embodiment, provided is an operation method for a DC/DC converter. The operation method includes: using a power stage for converting a DC input voltage into a DC output voltage, the power stage including an inductor; detecting whether the DC output voltage has an overshoot when the DC/DC converter is switched from a heavy loading into a light loading; when it is determined that the DC output voltage has the overshoot, forcing the DC/DC converter for additionally maintaining at a force continuous conduction mode (CCM) and thus discharging the DC output voltage by the inductor, and controlling the DC/DC converter switching from the force CCM into a discontinuous conductor mode (DCM).

### BRIEF DESCRIPTION OF THE DRAWINGS

FIG. 1 (prior art) shows an output voltage waveform and an inductor current waveform of the prior DC/DC converter.

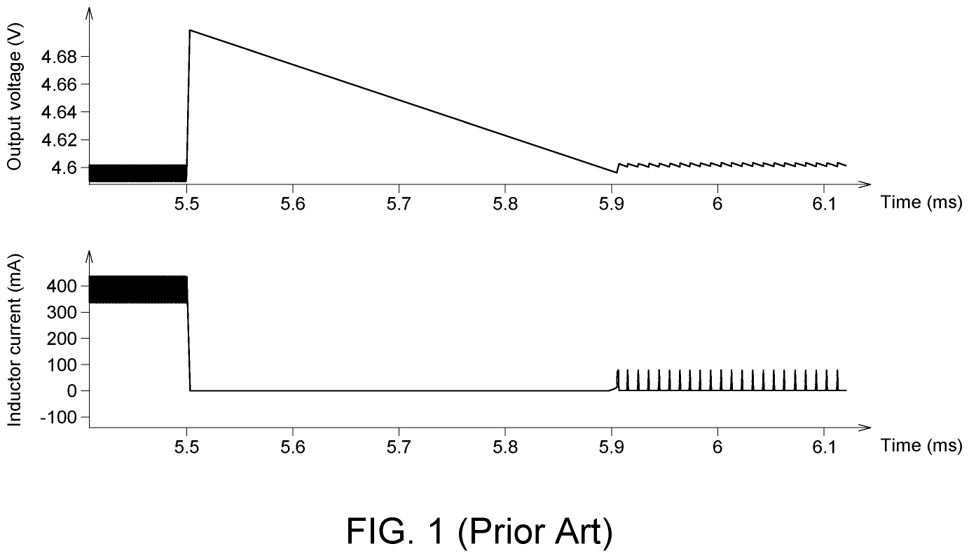

FIG. 2 shows a functional block diagram of a DC/DC converter according to one exemplary embodiment of the application.

FIG. 3 shows an output voltage waveform and an inductor current waveform of the DC/DC converter according to one exemplary embodiment of the application and an output voltage waveform and an inductor current waveform of the prior DC/DC converter.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DESCRIPTION OF THE EMBODIMENTS

Technical terms of the disclosure are based on general definition in the technical field of the disclosure. If the disclosure describes or explains one or some terms, definition of the terms is based on the description or explanation of the disclosure. Each of the disclosed embodiments has one or more technical features. In possible implementation, one skilled person in the art would selectively implement part or all technical features of any embodiment of the disclosure or selectively combine part or all technical features of the embodiments of the disclosure.

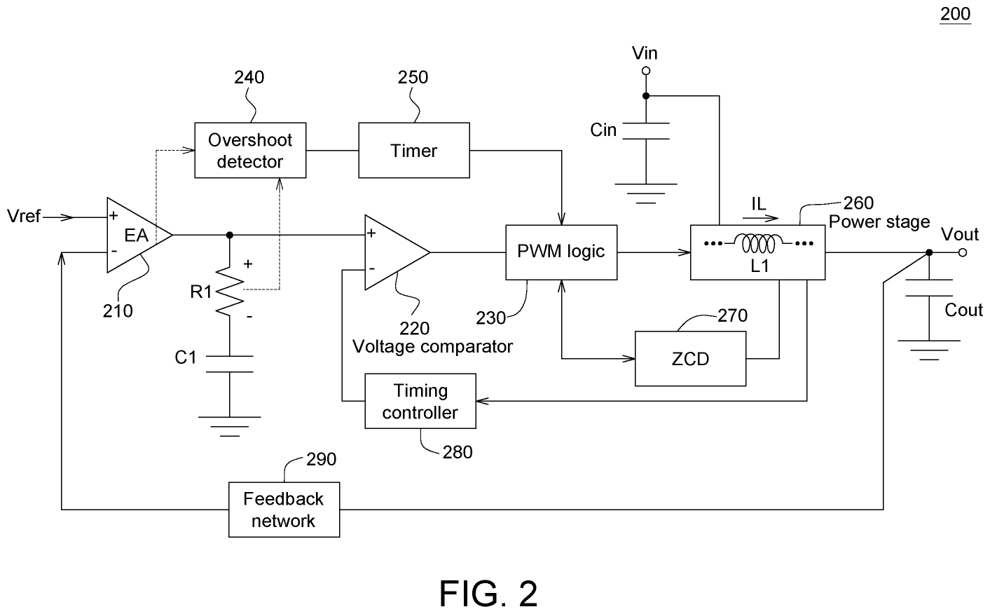

FIG. 2 shows a functional block diagram of a DC/DC converter according to one exemplary embodiment of the application. As shown in FIG. 2, the DC/DC converter 200 according to one exemplary embodiment of the application converts a DC input voltage Vin into a DC output voltage Vout. The DC/DC converter 200 includes: an error amplifier (EA) 210, a voltage comparator 220, a pulse width modulation (PWM) logic 230, an overshoot detector 240, a timer 250, a power stage 260, a zero current detector (ZCD) 270, a timing controller 280, a feedback network 290, a compensation circuit (including a resistor R1 and a capacitor C1), and decoupling capacitors Cin and Cout.

The EA 210 compares a reference voltage Vref and a feedback voltage (which is corresponding to the DC output voltage Vout) fed back from the feedback network 290. The EA 210 has an output signal (also referred as an error comparison result) which is input to the voltage comparator 220. The structure of the EA 210 is not specified here.

The voltage comparator 220 is coupled to the EA 210. The voltage comparator 220 compares the output signal from the EA 210 with an output signal from the timing controller 280. The output signal of the voltage comparator 220 is input into the PWM logic 230. The structure of the voltage comparator 220 is not specified here.

The PWM logic 230 is coupled to the voltage comparator 220. Based on the output signal from the voltage comparator 220 and the output signal from the ZCD 270, the PWM logic 230 controls the power stage 260. The voltage comparator 220 is coupled between the PWM logic 230 and the EA 210. The PWM logic 230 may further control the ZCD 270 to be disabled or enabled based on a timing period of the timer 250 (or said the overshoot event detection result of the overshoot detector 240). The structure of the PWM logic 230 is not specified here.

The overshoot detector 240 is coupled to the EA 210. The overshoot detector 240 detects whether an overshoot event occurs (or said whether the DC output voltage Vout has the overshoot), whose details will be described later. When the overshoot detector 240 detects the overshoot event, the overshoot detector 240 outputs a trigger signal to the timer 250 and thus the timer 250 starts to count timing. The structure of the overshoot detector 240 is not specified here.

The timer 250 is coupled to overshoot detector 240. In response to the trigger signal from the overshoot detector 240, the timer 250 counts timing during a timing period. Further, in beginning of the timing period, the timer 250 outputs a first control signal to the PWM logic 230 and in response to the first control signal, the PWM logic 230 controls the ZCD 270 from an enabled state into a disabled state. At end of the timing period, the timer 250 outputs a second control signal to the PWM logic 230 and in response to the second control signal, the PWM logic 230 controls the ZCD 270 from the disabled state into the enabled state. That is, during the timing period of the timer 250, the ZCD 270 is disabled. The structure of the timer 250 is not specified here.

The power stage 260 is coupled to the PWM logic 230. The power stage 260 is controlled by a control signal from the PWM logic 230 for performing voltage conversion to convert the DC input voltage Vin into the DC output voltage Vout. The structure of the power stage 260 is not specified here. For example, the power stage 260 may be a boost power stage, a buck power stage, an inverting power stage or a buck-boost power stage. Further, as shown in FIG. 2, the power stage 260 includes an inductor L. The coupling of the inductor L depends on the structure of the power stage 260. The inductor current IL flows through the inductor L.

The ZCD 270 is coupled to the PWM logic 230 and the power stage 260. As known, in light loading, if the inductor current IL flows in reverse direction (i.e. the inductor current IL has a negative value), the inductor L consumes additional power. Thus, the ZCD is used to prevent reverse of the inductor current IL. Besides, the ZCD 270 is also controlled by the PWM logic 230 to be disabled during the timing period of the timer 250. The structure of the ZCD 270 is not specified here.

The timing controller 280 is coupled to the voltage comparator 220 and the power stage 260. The timing controller 280 usually generates a ramp signal controlled by a constant frequency clock and may also add the ramp signal with a current signal representing an inductor current level sensed by the power stage 260. The structure of the timing controller 280 is not specified here.

The feedback network 290 is coupled to the EA 210. The feedback network 290 feeds back the DC output voltage Vout to the EA 210. The structure of the feedback network 290 is not specified here.

The resistor R1 and the capacitor C1 compose as a compensation circuit. The resistor R1 has two terminals coupled to the output terminal of the EA 210 and one terminal of the capacitor C1, respectively. The capacitor C1 has two terminals coupled to one terminal of the resistor R1 and ground, respectively. The positive terminal of the resistor R1 is defined as being coupled to the output terminal of the 210 and the negative terminal of the resistor R1 is defined as being coupled to the terminal of the capacitor C1.

The decoupling capacitor Cin removes power stage switching noise (which is caused by switching operations of the power stage 260) on the DC input voltage Vin. The decoupling capacitor Cin is coupled between the DC input voltage Vin and ground.

The decoupling capacitor Cout removes power stage switching noise (which is caused by switching operations of the power stage 260) on the DC output voltage Vout. The decoupling capacitor Cout is coupled between the DC output voltage Vout and ground.

In an exemplary embodiment of the application, the feedback network 290, the resistor R1, the capacitor C1, the voltage comparator 220, the EA 210 and the PWM logic 230 are also referred as a main control loop. The main control loop may generate a main loop control signal to control the DC/DC converter 200 to be selectively operated in either CCM or DCM.

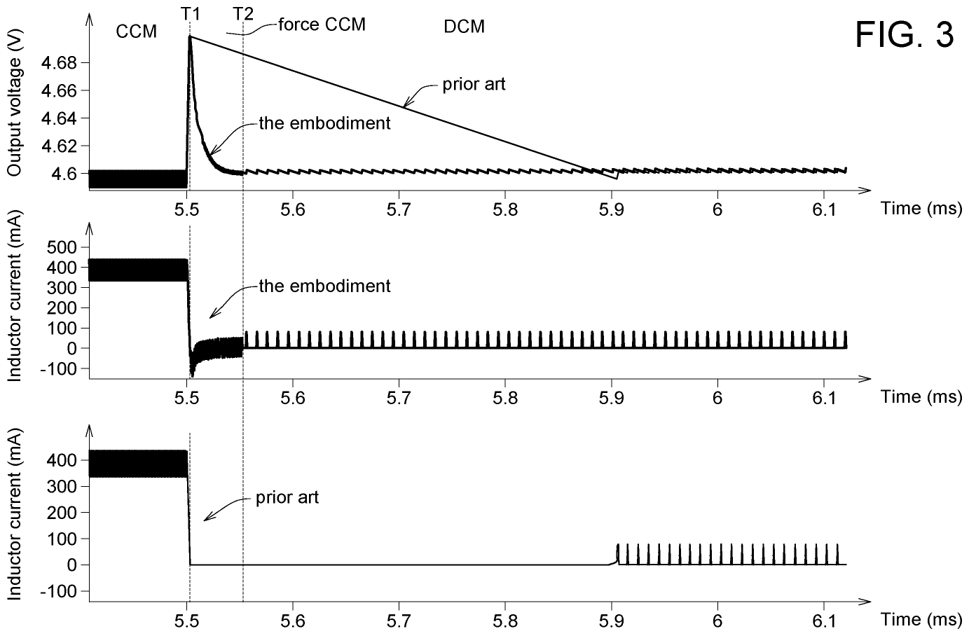

FIG. 3 shows an output voltage waveform and an inductor current waveform of the DC/DC converter according to one exemplary embodiment of the application and an output voltage waveform and an inductor current waveform of the prior DC/DC converter. Referring to FIG. 2 and FIG. 3.

In an exemplary embodiment of the application, the CCM operations and the DCM operations of the DC/DC converter 200 are not specified here. The following describes when switching from the heavy loading (at the timing T1) to the light loading, the DC/DC converter 200 rapidly discharges the overshoot of the DC output voltage Vout.

In switching from the heavy loading to the light loading, the DC output voltage Vout of the DC/DC converter 200 has an overshoot. When the overshoot of the DC output voltage Vout occurs, the sink current at the output terminal of the EA 210 is increased or said, because the sink current at the output terminal of the EA 210 is increased, the cross voltage of the resistor R1 is changed from a positive voltage to a negative voltage.

Thus, in an exemplary embodiment of the application, the overshoot detector 240 detects whether the sink current at the output terminal of the EA 210 is larger than a current threshold to decide whether an overshoot event occurs (the overshoot event indicating switching from the heavy loading to the light loading). If the overshoot detector 240 detects the sink current at the output terminal of the EA 210 is larger than the current threshold, the overshoot detector 240 decides the overshoot event occurs and vice versa.

Alternatively, the overshoot detector 240 may detect whether the cross voltage of the resistor R1 is changed from a positive voltage into a negative voltage and whether the cross voltage of the resistor R1 is lower than a voltage threshold (for example but not limited by 0V) to decide whether the overshoot event occurs. If the overshoot detector 240 detects that the cross voltage of the resistor R1 is changed from the positive voltage into the negative voltage and the cross voltage of the resistor R1 is lower than the voltage threshold, the overshoot detector 240 decides the overshoot event occurs and vice versa.

In an embodiment of the application, the overshoot event includes any one of the following: (1) the sink current at the output terminal of the EA 210 is larger than the current threshold; or (2) the cross voltage of the resistor R1 is changed from the positive voltage into the negative voltage and the cross voltage of the resistor R1 is lower than the voltage threshold.

When the overshoot detector 240 decides the overshoot event occurs, the overshoot detector 240 outputs a trigger signal to the timer 250.

When the timer 250 receives the trigger signal (which indicating that the overshoot event occurs) from the overshoot detector 240, the timer 250 starts to count the timing period (the length of the timing period is not specified here) and outputs a first control signal to the PWM logic 230. In response to the first control signal from the timer 250, the PWM logic 230 controls the ZCD 270 from the enabled state into the disabled state. When the ZCD 270 is disabled, the instantaneous average inductor current IL of the inductor L may be negative to facilitate discharge of the DC output voltage Vout (i.e. to facilitate discharge of the overshoot of the DC output voltage Vout). In an embodiment of the application, the timing period during which the ZCD is disabled is also referred as that the DC/DC converter 200 is at a force CCM state. This is because, in prior art, when switching from the heavy loading to the light loading, the DC/DC converter 200 is transited from CCM to DCM. On the contrary, in the embodiment of the application, the DC/DC converter 200 is forced to be at an additional CCM state (between the timing T1 and the timing T2 of FIG. 3).

After the timer 250 ends counting at the timing T2 of FIG. 3, the timer 250 outputs a second control signal to the PWM logic 230. In response to the second control signal from the timer 250, the PWM logic 230 controls the ZCD 270 from the disabled state into the enabled state. When the ZCD 270 is switched from the disabled state to the enabled state, due to the operations of the ZCD 270, the instantaneous average inductor current IL of the inductor L is prevented from being negative, i.e. the instantaneous average inductor current IL is recovered to 0 from the negative current. Then, the DC/DC converter 200 enters the DCM state. As shown in FIG. 3, at the timing T2, the overshoot of the DC output voltage Vout is almost discharged.

Thus, in an exemplary embodiment of the application, because the DC/DC converter 200 is forced to be at the additional CCM stage (between the timing T1 and the timing T2 of FIG. 3), the DC output voltage Vout is discharged by both the inductor L and the load and thus the overshoot is discharged more rapidly.

It will be apparent to those skilled in the art that various modifications and variations can be made to the disclosed embodiments. It is intended that the specification and examples be considered as exemplary only, with a true scope of the disclosure being indicated by the following claims and their equivalents.

1. A DC/DC converter including:
a power stage for converting a DC input voltage into a DC output voltage, the power stage including an inductor;
an overshoot detector for detecting whether the DC output voltage has an overshoot when the DC/DC converter is switched from a heavy loading into a light loading; and
a main control loop coupled to the power stage and the overshoot detector, when the overshoot detector determines that the DC output voltage has the overshoot, the main control loop forcing the DC/DC converter for additionally maintaining at a force continuous conduction mode (CCM) and thus the inductor discharging the DC output voltage, and then the main control loop controlling the DC/DC converter switching from the force CCM into a discontinuous conductor mode (DCM).

2. The DC/DC converter according to claim 1, further including:
a timer coupled to the main control loop and the overshoot detector,
wherein when the overshoot detector determines that the DC output voltage has the overshoot, the overshoot detector outputs a trigger signal to the timer, the timer counts a timing period in response to the trigger signal from the overshoot detector and during the timing period, the main control loop forces the DC/DC converter for maintaining at the force CCM and thus the inductor discharging the DC output voltage; and
at end of the timing period, the main control loop controls the DC/DC converter switching from the force CCM into the DCM.

3. The DC/DC converter according to claim 2, wherein the main control loop includes:
a feedback network coupled to an output terminal of the DC/DC converter for feeding back the DC output voltage as a feedback voltage, the feedback voltage being corresponding to the DC output voltage;
an error amplifier (EA) coupled to the feedback network, the EA compares a reference voltage and the feedback voltage;
a resistor having a positive terminal coupled to an output terminal of the EA and a negative terminal;
a capacitor coupled between the negative terminal of the resistor and ground;
a voltage comparator coupled to the EA for comparing an output signal of the EA and a ramp signal; and
a PWM (pulse width modulation) logic coupled to the voltage comparator and the timer.

4. The DC/DC converter according to claim 3, wherein the overshoot detector detects whether a sink current at the output terminal of the EA is larger than a current threshold to determine whether the DC output voltage has the overshoot.

5. The DC/DC converter according to claim 3, wherein the overshoot detector detects whether a cross voltage of the resistor changes from a positive voltage to a negative voltage and whether the cross voltage of the resistor is lower than a voltage threshold to determine whether the DC output voltage has the overshoot.

6. The DC/DC converter according to claim 5, further including a zero current detector (ZCD) coupled to the PWM logic and the power stage, the ZCD being controlled by the PWM logic, wherein the ZCD is disabled during the timing period and thus an instantaneous average inductor current of the inductor is negative for discharging the DC output voltage by the inductor.

7. An operation method for a DC/DC converter, the operation method including:
using a power stage for converting a DC input voltage into a DC output voltage, the power stage including an inductor;
detecting whether the DC output voltage has an overshoot when the DC/DC converter is switched from a heavy loading into a light loading;
when it is determined that the DC output voltage has the overshoot, forcing the DC/DC converter for additionally maintaining at a force continuous conduction mode (CCM) and thus discharging the DC output voltage by the inductor, and
controlling the DC/DC converter switching from the force CCM into a discontinuous conductor mode (DCM).

8. The operation method for the DC/DC converter according to claim 7, further including:
when it is determined that the DC output voltage has the overshoot, counting a timing period and during the timing period, forcing the DC/DC converter for maintaining at the force CCM and thus the inductor discharging the DC output voltage; and
at end of the timing period, controlling the DC/DC converter switching from the force CCM into the DCM.

9. The operation method for the DC/DC converter according to claim 8, wherein detecting whether a sink current at the output terminal of an EA of the DC/DC converter is larger than a current threshold to determine whether the DC output voltage has the overshoot.

10. The operation method for the DC/DC converter according to claim 8, wherein the DC/DC converter further including a resistor having a positive terminal coupled to an output terminal of the EA and a negative terminal; and a capacitor coupled between the negative terminal of the resistor and ground,
the operation method further including:
detecting whether a cross voltage of the resistor changes from a positive voltage to a negative voltage and whether the cross voltage of the resistor is lower than a voltage threshold to determine whether the DC output voltage has the overshoot.

11. The operation method for the DC/DC converter according to claim 10, further including during the timing period, disabling a ZCD of the DC/DC converter to allow an instantaneous average inductor current of the inductor is a negative current for discharging the DC output voltage by the inductor.
